(19) United States
(12) Patent Application Publication
(10) Pub. No.: US 2010/0155882 A1
(43) Pub. Date: Jun. 24, 2010

(54) METHOD FOR BONDING TWO SUBSTRATES

(76) Inventor: Arnaud Castex, Grenoble (FR)

Correspondence Address: WINSTON & STRAWN LLP;PATENT DEPARTMENT, 1700 K STREET, N.W., WASHINGTON, DC, 20006, US

(21) Appl. No.: 12/556,381

(22) Filed: Sep. 9, 2009

(30) Foreign Application Priority Data
Dec. 22, 2008 (EP) EP08291226

(51) Int. Cl. H01L 27/12; H01L 21/762

(52) U.S. Cl. 257/507; 438/459; 257/E21.567; 257/E27.112

(57) ABSTRACT

The invention relates to a method for bonding two substrates by applying an activation treatment to at least one of the substrates, and performing the contacting step of the two substrates under partial vacuum. Due to the combination of the two steps, it is possible to carry out the bonding and obtain high bonding energy with a reduced number of bonding voids. The invention is in particular applicable to a substrate of processed or at least partially processed devices.

### TECHNICAL FIELD

The invention relates to a method for bonding two substrates, and in particular to a method wherein at least one of the two substrates may comprise processed or at least partially processed devices. This kind of bonding situation occurs, for example, in the fabrication process of backside illuminated CMOS imager structures, when a first substrate comprising the opto-electronic devices of the CMOS imager are bonded to a second substrate. After bonding, the first substrate is thinned, preferentially by grinding, so that light can enter into the device via the backside.

During bonding, the adhesion between two substrates is achieved via molecular forces (Van de Waals forces). To achieve a high quality bonding and to facilitate the subsequent thinning step, it is mandatory to obtain a high bonding energy, at least in the range of 700 to 1000 mJ/m² or even more. In the prior art, high bonding energies are obtained by heating the assembled structure, typically to a temperature above 1000° C.

Unfortunately, there are situations in which it is not possible to expose the bonded assembly to such high temperatures. This is the case for instance if devices are present on one of the substrates, and the standard thermal treatment to improve the bonding energy cannot be carried out. Indeed, the high temperatures of about 1000 to about 1100° C. in the standard thermal treatment would have negative impacts on the functioning of the devices due to, for example, the spreading out of dopant concentrations or the diffusion of metals forming the devices. Using the mentioned temperature regime, a bonding energy in a range of 1.5 J/m² to 2 J/m² has been observed.

As an alternative to high temperature annealing of the bonded assembly, it has been proposed to reach high bonding energy by surface activation steps, for instance plasma activation followed by low temperature annealing, of the surfaces to be bonded. However, it has been observed that these steps could lead to bond voids, such as e.g., edge voids, thus eventually creating defects at the bonded interface. It has furthermore been observed that the higher the bonding energy, the higher the number of edge voids. This phenomenon has a negative impact on the fabrication yield, in particular in case that the non-transferred layers comprise electronic devices.

Thus, there is a need for improved bonding between substrates that include processed or at least partially processed devices, and the present invention now satisfies that need.

### SUMMARY OF THE INVENTION

The present invention provides a method for bonding with enhanced bonding energies that can be achieved in the absence of a high temperature thermal treatment. This method generally comprises the steps of a) applying an activation treatment to at least one of the two substrates, and b) performing the contacting step of the two substrates under partial vacuum. In particular, the method comprises the steps of providing each substrate with a surface for contact; applying an activation treatment to at least one surface of the two substrates to be bonded; and contacting the surfaces of the two substrates under partial vacuum to bond the substrates together.

It is the surprising finding of this invention that it is the combination of the two steps a) and b) that leads to the desired level in the bonding energy, namely of the order of 700 to 1000 mJoule/m² with a reduced number of edge voids compared to known bonding processes. Furthermore, by only applying a partial vacuum, which can easily be reached by using standard rough pumps only, the process is fast and easy to carry out. A high bonding quality, namely no edge voids or at least a reduced number of edge voids, can be achieved even with two substrates having thermal expansion coefficients which are so different that the standard thermal anneal methods cannot be applied.

Finally, the bonding quality observed with the inventive method is sufficient to carry out a layer transfer according to the Smart Cut™ layer transfer technology, where ions are implanted into a donor wafer to define a plane of weakness. The bonded assembly comprising the donor wafer can then be split in the absence or with a reduced number of edge defects and despite the use of relatively low temperatures.

The invention also relates to the opto-electronic devices that include the substrates fabricated according to one of the methods described herein.

### BRIEF DESCRIPTION OF THE DRAWING FIGURES

Advantageous embodiments of the invention will now be described in detail with respect to the following Figures, wherein:

FIGS. 1a-1g illustrate one embodiment of the bonding method according to the invention.

### DETAILED DESCRIPTION OF THE INVENTION

In this invention, at least one of the two substrates can comprise processed or at least partially processed devices. In this context, the term “device” relates to any structure on at least one of the substrates which at least partially belongs to the final devices such as electronic devices or opto-electronic devices comprising, amongst others, capacitor and/or transistor structures. It is the particular advantage of the invention that it can be applied to any bonded structure that requires high bonding energy but cannot be exposed to high temperature and/or that suffers from the presence of edge voids. This is the case when devices are present in or on one of the substrates.

According to an advantageous embodiment of the invention, the partial vacuum used in the contacting step can have a pressure of 1 to 50 Torr (1.33 to 66.7 mbar), preferably 1 to 20 Torr (1.33 to 26.6 mbar), preferably between 10 to 20 Torr (13.3 to 26.6 mbar). This level of vacuum can be easily and rapidly be reached with rough pumps, which at the same time have a cost advantage. There is thus no need to go up to a secondary vacuum to reach the desired bonding energy and a reduced level of defects.

Advantageously, the contacting step can be carried out at room temperature, in particular at a temperature in the range of 18 to 26° C. The possibility to carry out the contacting step which is under partial vacuum and which is at room temperature facilitates the practical realisation of the process.

The surfaces of both substrates are typically flat and polished to facilitate molecular bonding therebetween during the contacting step. At least one of the substrates comprises processed or at least partially processed devices are on the surface or within the substrate. The devices can be provided within the substrate by first providing the processed devices on the surface of one substrate, and then providing a dielectric layer over the processed devices as the surface of that substrate. The surface of the dielectric layer is subsequently bonded to the surface of the other substrate. The dielectric layer is typically an oxide layer and the substrates comprise silicon so that a silicon on insulator structure can be achieved.

Preferably, after bonding and during subsequent treatment steps, the bonded substrates are exposed to temperatures of at most 500° C., preferably at most 300° C. With the inventive method, the bonding energy is high enough for the subsequent treatments and at the same a reduced number of bonding voids compared to the prior art is observed, which in turn improves the bonding. Furthermore, degradation of devices such as back side imagers in already processed layers, e.g., due to diffusion of metals, fusion of metallic lines and/or contacts can be prevented.

According to a preferred embodiment, the activation treatment can comprise at least one of a plasma activation, a polishing step, a cleaning step and a brushing step of the surface or surfaces to be bonded. In this context, it is further preferred that the activation treatment for a substrate without processed or at least partially processed devices comprises a cleaning step, a plasma activation, a cleaning step and a brushing step, in this order. Furthermore, concerning the activation treatment for a substrate with processed or at least partially processed devices, the activation treatment can preferably comprise a polishing step and a cleaning step in this order. Further preferred, the activation treatment can further comprise a plasma activation step and/or brushing step after the cleaning. With these treatments, further optimised results concerning the bonding energy are achievable.

According to an advantageous embodiment, the contacting step can be carried out in a dry atmosphere, in particular one that contains less than 100 ppm H₂O molecules. The dry atmosphere further reduces the occurrence of defects, in particular of edge voids.

More advantageously, the contacting step can be carried out in a neutral atmosphere, in particular in an argon and/or nitrogen atmosphere.

According to a preferred variant, the inventive method can further comprise the step of providing a dielectric layer, in particular an oxide layer, over the processed devices wherein bonding occurs between the surface of the dielectric layer and one surface of the second substrate. This dielectric layer can, for instance, be a PECVD deposited oxide which, furthermore, is planarized to represent a surface roughness of less than 5 Å RMS. Thus, bonding can be carried out independently of the topology of the processed device structures on at least one of the substrates under predetermined conditions.

If desired, the inventive method can comprise an additional step of thinning at least one of the two substrates after bonding. As a consequence of the high bonding energy achieved and the reduced number of bonding voids according to the inventive method, it is thus possible to carry out the thinning after bonding even after a limited thermal treatment.

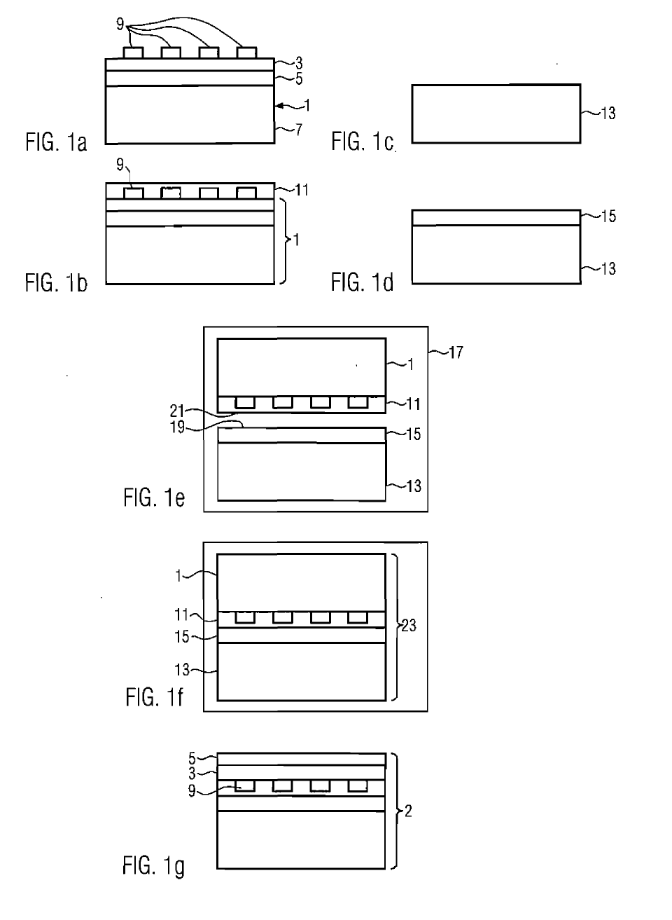

FIG. 1a illustrates a first substrate 1, which is also called a donor substrate. In this embodiment, the donor substrate is a silicon on insulator (SOI) wafer with a silicon layer 3 provided on a buried oxide layer 5 in turn provided on a base substrate 7, e.g., a silicon wafer. Instead of an SOI substrate, any other suitable substrate such as a plain silicon wafer, a germanium arsenide wafer or a germanium on insulator, etc. can be used as the first substrate 1. Processed devices 9, such as electronic devices or opto-electronic devices, already have been fabricated in and/or on the semiconductor layer 3 of the first substrate 1. Typically, the semiconductor layer 3, together with these devices 9, has a thickness of about 2 to 30 μm, for instance about 15 μm. The devices 9 present on the first substrate 1 can be completely processed or only partially processed, meaning that, in subsequent process steps, the devices will be finalised, e.g., by provided electric connections, etc.

FIG. 1b illustrates the next step of the method which consists in providing a dielectric layer 11, for example an oxide, on the devices 9. The dielectric layer 11 in this embodiment is deposited using a suitable process, such as plasma enhanced CVD. Following the deposition of this layer 11, a planarization step is carried out, e.g. using chemical mechanical polishing CMP, to obtain a surface roughness of less than 5 Å RMS, so that the dielectric layer 11 can serve as a leveling layer.

FIG. 1c illustrates a second substrate 13, here called the support substrate, which is typically a silicon wafer, but could also be made out of any other suitable material. Prior to bonding, an oxidation step is carried out to provide an oxide layer 15 on the support substrate 13 with a thickness of about 0.5 to 2.5 μm. Alternatively, the subsequent bonding is performed without any oxide formation step or by depositing the oxide on the support substrate.

The donor substrate 1 with the devices and the dielectric layer 11 and/or the support substrate 13 with its oxide layer 15, as illustrated in FIG. 1d, are then activated.

In the case of the donor substrate 1 activation, first of all a further second polishing step is carried out. The removal of material is typically less than 1 micron or even less than 0.3 micron so that the surface is activated and prepared for bonding. The polishing step is followed by a cleaning step, which can for instance comprise scrubbing of the surface and SC1 cleaning to remove particles or polishing slurry residue. These steps are carried out on the surface of the dielectric layer 11, which represents the surface at which bonding will occur in the subsequent process step. In some instances, however, this polishing step can be omitted.

According to a variant, activation of the donor substrate can be complemented by a plasma activation using an O₂ and/or N₂ plasma with or without a subsequent brushing step. This step may include exposure of the donor substrate surface to be bonded to an oxygen plasma or a plasma containing O₂. The plasma exposure tool can be, for example, a Reactive Ion Etching (RIE) tool, with a plasma power of about 100 W to 1000 W for a 200 mm wafer and a plasma pressure of about 1 to 100 mTorr (1.33 mbar to 133 mbar).

The support substrate 13 activation also includes in cleaning of the surface, for instance using SC1 30 to 80° C. for about 10 min, an O₂ and/or N₂ plasma activation under the same conditions as mentioned above, a further cleaning and a final brushing step of the surface of oxide layer 15 at which bonding will occur in a subsequent process step. Other conventional cleaning and brushing steps can be used if desired.

The role of the activation process step is to prepare the surfaces for bonding so that high bonding energies can be achieved. Typically, for molecular bonding or molecular adhesion bonding, i.e., a technique that is known to the skilled person as “wafer bonding” or “direct bonding”, in which no adhesive is used, the surfaces of the substrates that are to be brought into contact are prepared to be flat and polished.

Subsequently, illustrated in FIG. 1e, the first and second substrates are placed into a bonding chamber 17 with the surface 19 of the oxide layer 15 on the support substrate 13 facing the surface 21 of the dielectric layer 11 on the donor substrate 1. Typically, both substrates are aligned with respect to their notches. After the introduction of the substrates and their alignment, the chamber is closed and pumped down to a vacuum in the order of 1 to 50 Torr, preferably 1 to 20 Torr, and even preferably between 10 to 20 Torr. Typically, this takes about 2 to 3 minutes and, for the purpose of the invention, this level of partial vacuum provides the increase in bonding energy in a reasonable time, e.g., compared to high or ultra high vacuum. Furthermore less sophisticated vacuum pumps, such as primary rough pumps are sufficient to carry out the invention.

The atmosphere in the bonding chamber in the embodiment is essentially composed of a dry atmosphere, in particular with less than 100 ppm H₂O molecules, and/or further preferred of a neutral atmosphere, composed for instance of argon and/or nitrogen. The bonding chamber is kept at room temperature, thus in a range of 18° C. to 26° C.

When the desired pressure level is reached, the two surfaces 19 and 21 are brought into contact, as illustrated in FIG. 1f, and bonding is initiated. Typically, bonding starts at one point and a bonding wave spreads out so that, in the end, surfaces 19 and 21 are attached to each other via molecular adhesive forces (van der Waals forces) and form a donor-support compound 23. The initial contact can be achieved by applying a slight pressure on the side or in the center, for instance by the use of a mechanical finger or other localized pressure applying device.

With the described bonding method, due to the advantageous synergistic effects of carrying out the surface activation steps in combination with the contacting under partial vacuum, bonding energies in a range of at least 700 to 1000 mJoule/m² with a reduced level of or even without bonding defects are achieved. In addition, these results are achieved without having to carry out a post-bonding anneal at high temperatures of greater than 500° C. It has been observed that the occurrence of edge voids can be suppressed or limited (by at least one order of magnitude compared to the prior art bonding methods) except for voids arising from the presence of particles on one of the surfaces before bonding.

According to a variant of the embodiment, the donor substrate 1 can be thinned down, as illustrated in FIG. 1g. Thinning can be achieved by a grinding and/or a polishing step, followed by a chemical etch that stops on the buried oxide 5 of the initial SOI donor substrate 1. Eventually, additional finishing steps, such as edge polishing and/or grinding, can be performed. The thinning does not necessarily stop at the buried oxide 5. According to further variants, even this oxide layer 5 could also be removed. In this layer 3 and eventually 5 are transferred on the second substrate. In this case, the inventive bonding method shows further advantageous effects as, again due to the high bonding energy achieved, the edge of the transferred layer is of high quality, it shows a regular outline, no cracking or tearing off on the edge of the wafer due to the mechanical thinning of the donor wafer.

As illustrated in FIG. 1g, the initial devices 9 of the SOI device layer 3 have now been transferred onto the support substrate 13. To complete the devices, additional processing steps, such as electrical connection etc, can be performed.

In addition, the structure 25 of FIG. 1g might serve as a support substrate 13 in subsequent fabrication process steps. In this case, both the donor substrate and the support substrate can comprise devices.

In opto-electronic applications, the structure as illustrated in FIG. 1g will receive light via the buried oxide layer 5 so that it impinges on the backside of electronic devices 9.

According to a variant, the thinning could also be achieved using the Smart Cut™ layer transfer technology. In this case, prior to bonding, light species such as helium or hydrogen are implanted into the donor substrate 1 to form a predetermined splitting area. Splitting is then achieved during or after the exposition of the bonded 23 assembly, as illustrated in FIG. 1f to higher than room temperature, e.g., in the range of 300 to 500° C.

In this embodiment the first substrate 1 carries already devices 9 on it. The invention is nevertheless not limited to this kind of situation as any substrate with our without device structures can be processed according to the invention and thus achieve high bonding energy and reduced edge void concentration.

1. A method for bonding two substrates comprising the steps of:
providing each substrate with a surface for contact;
applying an activation treatment to at least one surface of the two substrates to be bonded; and
contacting the surfaces of the two substrates under partial vacuum to bond the substrates together.

2. The method according to claim 1, wherein the surfaces of both substrates are flat and polished to facilitate molecular bonding therebetween during the contacting step.

3. The method according to claim 1, wherein at least one of the substrates comprises processed or at least partially processed devices are on the surface or within the substrate.

4. The method according to claim 3, wherein the devices are present within the substrate by providing the processed devices on the surface of one substrate, and providing a dielectric layer over the processed devices as the surface of that substrate, wherein the surface of the dielectric layer is bonded to the surface of the other substrate.

5. The method according to claim 4, wherein the dielectric layer is an oxide layer and the substrates comprise silicon so that a silicon on insulator structure can be achieved.

6. The method according to claim 1, wherein the partial vacuum has a pressure of 1 to 50 Torr (1.33 to 66.7 mbar).

7. The method according to claim 1, wherein the contacting step is carried out at a temperature of from 18° C. to 26° C.

8. The method according to claim 1, wherein the bonded substrates have a bonding energy of about 700 to 1000 mJoule/m² and a reduced number of edge voids compared to substrates conventionally bonded at temperatures of above 1000° C.

9. The method according to claim 1, wherein after bonding and during subsequent treatment steps, the bonded substrates are exposed to temperatures of at most 300° C. to 500° C.

10. The method according to claim 1, wherein the activation treatment comprises at least one of a plasma activation, a polishing step, a cleaning step or a brushing step conducted on the surface of one or both of the substrates.

11. The method according to claim 3, wherein the activation treatment for the substrate that includes the processed devices comprises conducting sequentially a cleaning step, a plasma activation, a cleaning step and a brushing step.

12. The method according to claim 3, wherein the activation treatment for the substrate that includes the processed devices comprises conducting sequentially a polishing step and a cleaning step.

13. The method according to claim 12, wherein the activation treatment further comprises a plasma activation step or brushing step after the cleaning step.

14. The method according to claim 1, wherein the contacting step is carried out in a dry atmosphere that contains less than 100 ppm H₂O molecules.

15. The method according to claim 1, wherein the contacting step is carried out in a neutral atmosphere that contains argon, nitrogen or mixtures thereof.

16. The method according to claim 1, further comprising a step of thinning at least one of the two substrates after bonding.

17. An electronic or opto-electronic device comprising a bonded substrate fabricated according to the method of claim 1.
